(19) United States
(12) Patent Application Publication
(10) Pub. No.: US 2026/0047123 A1
(43) Pub. Date: Feb. 12, 2026

(54) SEMICONDUCTOR DEVICE, SEMICONDUCTOR MODULE, AND WIRELESS COMMUNICATION APPARATUS

(71) Applicant: Sony Group Corporation, Tokyo (JP)

(72) Inventor: Kunihiko Tasai, Tokyo (JP)

(21) Appl. No.: 19/100,311

(22) PCT Filed: Aug. 15, 2023
(86) PCT No.: PCT/JP2023/029492

§ 371 Date: Jan. 31, 2025

(30) Foreign Application Priority Data
Sep. 1, 2022 (JP) 2022-139301

(51) Int. Cl. H10D 30/47; H10D 30/01; H10D 62/85

(52) U.S. Cl. CPC H10D 30/475; H10D 30/015; H10D 62/8503

(57) ABSTRACT

This semiconductor device includes a substrate, a channel layer provided on one side of a surface of the substrate and including a first nitride semiconductor having a first bandgap, a barrier layer provided on an opposite side of the channel layer from the substrate and including a second nitride semiconductor that includes Alₓ₁In_{y1}Ga_{(1-x1-y1)}N (0<x1<1, 0<y1<1) and has a second bandgap larger than the first bandgap of the first nitride semiconductor, and an intermediate layer provided in the barrier layer and including a third nitride semiconductor that includes Alₓ₂In_{y2}Ga_{(1-x2-y2)}N (0≤x2<1, 0≤y2<1), and the semiconductor device satisfies (1−x1−y1)<(1−x2−y2).

### TECHNICAL FIELD

The present disclosure relates to a semiconductor device, a semiconductor module, and a wireless communication apparatus.

### BACKGROUND ART

For example, Patent Literature 1 discloses an epitaxial substrate for a semiconductor device that enables good ohmic contact to be obtained in a high electron mobility transistor (HEMT). This epitaxial substrate for a semiconductor device includes a base substrate, a channel layer including GaN, a spacer layer including AlN, and a barrier layer including In, Al, or Ga as a Group III element. The barrier layer is substantially configured by doping a Ga atom in a matrix layer including InₓAl₁₋ₓN (0<x<1), and a concentration of the Ga atom in the barrier layer is 1.2×10²⁰ cm⁻³ or less.

### CITATION LIST

### Patent Literature

Patent Literature 1: Japanese Unexamined Patent Application Publication No. 2011-222964

### SUMMARY OF THE INVENTION

Meanwhile, it is desired to improve heat resistance in a HEMT.

Thus, it is desirable to provide a semiconductor device, a semiconductor module, and a wireless communication apparatus that enable an improvement in heat resistance.

A semiconductor device according to one embodiment of the present disclosure includes a substrate, a channel layer provided on one side of a surface of the substrate, the channel layer including a first nitride semiconductor having a first bandgap; a barrier layer provided on an opposite side of the channel layer from the substrate and including a second nitride semiconductor, the second nitride semiconductor including Alₓ₁In_{y1}Ga_{(1-x1-y1)}N (0<x1<1, 0<y1<1) and having a second bandgap larger than the first bandgap of the first nitride semiconductor; and an intermediate layer provided within the barrier layer and including a third nitride semiconductor, the third nitride semiconductor including Alₓ₂In_{y2}Ga_{(1-x2-y2)}N (0≤x2<1, 0≤y2<1), in which (1−x1−y1)<(1−x2−y2) is satisfied.

A semiconductor module according to one embodiment of the present disclosure includes a semiconductor device of one embodiment of the present disclosure described above.

A wireless communication apparatus according to one embodiment of the present disclosure includes a semiconductor device of one embodiment of the present disclosure described above.

In a semiconductor device according to one embodiment of, a semiconductor module according to one embodiment of, and a wireless communication apparatus according to one embodiment of the present disclosure, an intermediate layer including a third nitride semiconductor that includes Alₓ₂In_{y2}Ga_{(1-x2-y2)}N (0≤x2<1, 0≤y2<1) and satisfies (1−x1−y1)<(1−x2−y2) is provided within a barrier layer that includes a second nitride semiconductor including Alₓ₁In_{y1}Ga_{(1-x1-y1)}N (0<x1<1, 0<y1<1) and having a second bandgap larger than the first bandgap of the first nitride semiconductor included in the channel layer. This improves a crystallinity of the barrier layer.

### BRIEF DESCRIPTION OF THE DRAWINGS

FIG. 1 is a schematic cross-sectional view illustrating an example of a configuration of a semiconductor device according to an embodiment of the present disclosure.

FIG. 2A is a schematic cross-sectional view illustrating an example of a process of manufacturing the semiconductor device illustrated in FIG. 1.

FIG. 2B is a schematic cross-sectional view illustrating a process subsequent to FIG. 2A.

FIG. 2C is a schematic cross-sectional view illustrating a process subsequent to FIG. 2B.

FIG. 2D is a schematic cross-sectional view illustrating a process subsequent to FIG. 2C.

FIG. 2E is a schematic cross-sectional view illustrating a process subsequent to FIG. 2D.

FIG. 2F is a schematic cross-sectional view illustrating a process subsequent to FIG. 2E.

FIG. 3 is a schematic cross-sectional view illustrating an example of a configuration of a semiconductor device according to Modification Example 1 of the present disclosure.

FIG. 4 is a schematic cross-sectional view illustrating another example of the configuration of the semiconductor device according to Modification Example 1 of the present disclosure.

FIG. 5 is a schematic cross-sectional view illustrating an example of a configuration of a semiconductor device according to Modification Example 2 of the present disclosure.

FIG. 6 is a schematic cross-sectional view illustrating an example of a configuration of a semiconductor device according to Modification Example 3 of the present disclosure.

FIG. 7 is a schematic cross-sectional view illustrating another example of the configuration of the semiconductor device according to Modification Example 3 of the present disclosure.

FIG. 8 is a schematic cross-sectional view illustrating an example of a configuration of a semiconductor device according to Modification Example 4 of the present disclosure.

FIG. 9 is a schematic cross-sectional view illustrating an example of a configuration of a semiconductor device according to Modification Example 5 of the present disclosure.

FIG. 10 is a schematic cross-sectional view illustrating a configuration of a semiconductor device of Reference Example 1.

FIG. 11 is a schematic cross-sectional view illustrating a configuration of a semiconductor device of Reference Example 2.

FIG. 12 is a schematic cross-sectional view illustrating a configuration of a semiconductor device of Reference Example 3.

FIG. 13 is a schematic cross-sectional view illustrating a configuration of a semiconductor device of Reference Example 4.

FIG. 14 is a characteristic diagram illustrating an off-leakage current in Reference Example 4.

FIG. 15 is a characteristic diagram illustrating an off-leakage current in Example.

FIG. 16 illustrates a current-voltage characteristic in Reference Example 2.

FIG. 17 illustrates a current-voltage characteristic in Example.

FIG. 18 is a schematic perspective view illustrating a configuration of a semiconductor module.

FIG. 19 is a block diagram illustrating a configuration of a wireless communication apparatus.

### MODES FOR CARRYING OUT THE INVENTION

In the following, some embodiments of the present disclosure are described in detail with reference to the drawings. The embodiments described below are specific examples of the present disclosure, and the present disclosure is not limited to the following embodiments. In addition, the arrangement, dimensions, dimension ratios, and the like of components in the present disclosure are not limited to those illustrated in each drawing.

It should be noted that the explanation is given in the following order.
1. Embodiment (an example of a semiconductor device having a Schottky-type gate configuration in which an intermediate layer is inserted into a barrier layer)
   1-1. Configuration of Semiconductor Device
   1-2. Method of Manufacturing Semiconductor Device
   1-3. Workings and Effects
2. Modification Examples
   2-1. Modification Example 1
   2-2. Modification Example 2
   2-3. Modification Example 3
   2-4. Modification Example 4
   2-5. Modification Example 5
3. Examples
4. Application Examples
   4-1. Example of Application to Semiconductor Module
   4-2. Example of Application to Wireless Communication Apparatus

### 1. EMBODIMENT

### 1-1. Configuration of Semiconductor Device

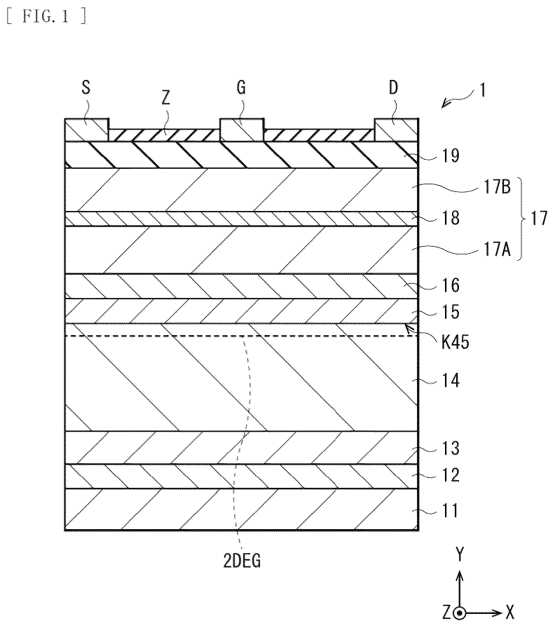

FIG. 1 schematically illustrates an example of a cross-sectional configuration of a semiconductor device (semiconductor device 1) according to an embodiment of the present disclosure.

The semiconductor device 1 has a stacked configuration in which a substrate 11, a first buffer layer 12, a second buffer layer 13, a channel layer 14, a first spacer layer 15, a second spacer layer 16, a barrier layer 17, an intermediate layer 18 provided within the barrier layer 17, and a protective layer 19 are stacked in sequence. The semiconductor device 1 further includes a source electrode S, a drain D, an insulating film Z, and a gate electrode G on the protective layer 19. The semiconductor device 1 has, for example, a Schottky-type gate configuration.

The semiconductor device 1 according to the present embodiment is a high electron mobility transistor (HIEMT) having a two-dimensional electron gas layer 2DEG as a channel. The two-dimensional electron gas layer 2DEG is formed due to a difference in a magnitude of polarization between the channel layer 14 and the barrier layer 17. The two-dimensional electron gas layer 2DEG is formed in the channel layer 14, for example, adjacent to an interface K45 between the channel layer 14 and the first spacer layer 15.

The substrate 11 is a support for the semiconductor device 1. For example, the substrate 11 is a Si (silicon) substrate, a SiC (silicon carbide) substrate, a sapphire substrate, a GaN (gallium nitride) substrate, an AlN (aluminum nitride) substrate, or the like. As a Si substrate, for example, a single crystal Si(111) substrate having a (111) plane as a main surface is preferred. In the semiconductor device 1, the first buffer layer 12 and the second buffer layer 13 are provided as described above. The first buffer layer 12 and the second buffer layer 13 make it possible to reduce a mismatch between a lattice constant of the substrate 11 and that of the channel layer 14. For this reason, the substrate 11 may include a material having a lattice constant different from that of the channel layer 14.

It should be noted that the substrate 11 using the above material makes it possible to obtain the effect of the semiconductor device of the present disclosure described below. The Example and Reference Examples 1 to 4 described below are each a result obtained in the case of using the substrate 11 including Si(111). It is possible to expect a further reduction in off-leakage current and a higher breakdown voltage of the semiconductor device 1 using a substrate including SiC or a substrate including GaN, which has a higher single crystallinity and allows a lower through-dislocation density than Si(111). For this reason, it is sufficient to configure the substrate 11 by selecting a preferable material depending on the application or the like.

The first buffer layer 12 and the second buffer layer 13 each include an epitaxially grown nitride semiconductor. The first buffer layer 12 and the second buffer layer 13 make it possible to reduce a lattice mismatch between the substrate 11 and the channel layer 14 by controlling a lattice constant of a surface in which the channel layer 14 is provided. This makes it possible for the first buffer layer 12 and the second buffer layer 13 to further improve a crystalline state of the channel layer 14 while suppressing warpage of the substrate 11.

For example, in a case where the substrate 11 is a single crystal Si substrate having a (111) plane as a main surface and the channel layer 14 is a GaN layer, the first buffer layer 12 includes AlN and the second buffer layer 13 includes AlGaN. However, depending on the configuration of the substrate 11 and the channel layer 14, neither the first buffer layer 12 nor the second buffer layer may be present. Alternatively, of the first buffer layer 12 and the second buffer layer, only the first buffer layer 12 may be provided.

The channel layer 14 includes a nitride semiconductor having a bandgap smaller than the bandgap of the first spacer layer 15 and the bandgap of the barrier layer 17. The channel layer 14 is provided on the second buffer layer 13. The channel layer 14 allows a carrier to accumulate at an interface on the barrier layer 17 side due to a difference in a magnitude of polarization between the channel layer 14 and the barrier layer 17.

The channel layer 14 includes Alₓ₆In_{y6}Ga_{(1-x6-y6)}N (0≤x6≤1, 0≤y6≤1, 0≤x6+y6≤1), which is an epitaxially grown nitride semiconductor. For example, the channel layer 14 includes epitaxially gown GaN (gallium nitride). The channel layer 14 may include undoped u-GaN with no added impurity. In addition, the channel layer 14 may include at least one type of InGaN (indium gallium nitride), InN (indium nitride), AlGaN (aluminum gallium nitride), or AlInGaN (aluminum indium gallium nitride). Furthermore, the channel layer 14 may have a stacked configuration including a plurality of layers each having a different composition. In such cases, the channel layer 14 makes it possible to suppress impurity scattering of a carrier. This allows the channel layer 14 to further increase a carrier mobility.

The first spacer layer 15 includes a nitride semiconductor having a larger bandgap than the bandgap of the channel layer 14. The first spacer layer 15 is provided above the channel layer 14. The first spacer layer 15 is provided to reduce alloy scattering between the barrier layer 17 and the channel layer 14 and to suppress a decrease in carrier mobility of the two-dimensional electron gas layer 2DEG due to the alloy scattering.

The first spacer layer 15 includes epitaxially grown Alₓ₄In_{y4}Ga_{(1-x4-y4)}N (0<x4≤1, 0≤y4<1, 0≤x4+y4≤1). For example, the first spacer layer 151 may include AlN or may include AlGaN or AlInGaN.

It is preferable for the first spacer layer 15 to have a thickness of, for example, 0.26 nm or more and 3.0 nm or less, and particularly preferable to have a thickness of 0.5 nm or more and 1.5 nm or less. In a case where the first spacer layer 15 has a thickness of 0.26 nm or more, it is possible to expect that the first spacer layer 15 is more effective in suppressing alloy scattering. On the other hand, in a case where the first spacer layer 15 has a thickness of 3.0 nm or less, it is possible for the first spacer layer 15 to control a bandgap profile of the semiconductor device 1 more appropriately. This makes it possible to further increase a carrier density of the two-dimensional electron gas layer 2DEG formed in the channel layer 14.

The second spacer layer 16 includes Alₓ₅In_{y5}Ga_{(1-x5-y5)}N (0<x5<1, 0≤y5<1, 0<x5+y5<1), which is an epitaxially grown nitride semiconductor. The second spacer layer 16 is provided on the first spacer layer 15. The Alₓ₅In_{y5}Ga_{(1-x5-y5)}N included in the second spacer layer 16 has a relationship of x5<x1 with respect to Alₓ₁In_{y1}Ga_{(1-x1-y1)}N (0<x1≤1, 0≤y1<1), which is a nitride semiconductor included in the barrier layer 17 described below. This makes it easier to obtain a mixed crystal having a higher single crystallinity than the barrier layer 17. Accordingly, it is possible for the second spacer layer 16 to define an interface between the barrier layer 17 and the first spacer layer 15 more clearly while suppressing interface disorder due to heat, thus making it possible to suppress a degradation of a layer configuration of the channel layer 14 and the barrier layer 17 due to heat.

The second spacer layer 16 may include GaN, for example, and the second spacer layer 16 includes AlGaN or AlInGaN. For example, the second spacer layer 16 including GaN may be provided on the first spacer layer 15 including AlN. Alternatively, the second spacer layer 16 including AlGaN may be provided on the first spacer layer 15 including AlGaN. In a case where an AlN layer and a GaN layer are stacked, diffusion of Al from the AlN layer to the GaN layer or diffusion of Ga from the GaN layer to the AlN layer is likely to be caused. This gives a manufacturing advantage to a configuration in which both the first spacer layer 15 and the second spacer layer 16 include AlGaN. Furthermore, the second spacer layer 16 including AlInGaN may be provided on the first spacer layer 15 including AlInGaN. In addition, because an AlInGaN layer including In allows lattice distortion to be reduced, it is possible to obtain an effect of suppressing a generation of a defect in the first spacer layer 15 and a defect in the second spacer layer 16.

It is preferable that a Ga composition (1−x5−y5) of the Alₓ₅In_{y5}Ga_{(1-x5-y5)}N included in the second spacer layer 16 be 0.3 or more. In a case where the Ga composition (1−x5−y5) of the second spacer layer 16 is 0.3 or more, the crystallinity of the second spacer layer 16 is further improved, allowing suppression of interface disorder due to heat. Thus, it is possible to suppress the degradation of the layer configuration of the channel layer 14 and the barrier layer 17 due to heat. It is sufficient that the composition ratio of Al in the second spacer layer 16 is lower than both the composition ratio of Al in the first spacer layer 15 and the composition ratio of Al in the barrier layer 17. Inserting the second spacer layer 16 having a relatively low composition ratio of Al between the first spacer layer 15 and the barrier layer 17 makes it possible to improve the single crystallinity of the barrier layer 17 including AlInGaN. In other words, inserting the second spacer layer 16 having a higher Ga concentration than the Ga concentration in the first spacer layer 15 and the Ga concentration in the barrier layer 17 between the first spacer layer 15 and the barrier layer 17 allows the single crystallinity of the barrier layer 17 including AlInGaN to be improved. Further, to put it in other words, the semiconductor device 1 has a configuration in which the second spacer layer 16 having a bandgap lower than both the bandgap of the first spacer layer 15 and the bandgap of the barrier layer 17 is provided between the first spacer layer 15 and the barrier layer 17. This realizes suppression of local electric field concentration and high-speed on/off operation, making it possible to obtain a higher breakdown voltage and a high mutual conductance.

It is preferable for the second spacer layer 16 to have a thickness of 0.26 nm or more and 3.0 nm or less, and particularly preferable to have a thickness of 0.5 nm or more and 1.5 nm or less. In a case where the second spacer layer 16 has a thickness of 0.26 nm or more, it is possible to perform layer formation of the second spacer layer 16 more easily. On the other hand, in a case where the second spacer layer 16 has a thickness of 3.0 nm or less, it is possible for the second spacer layer 16 to control the bandgap profile of the semiconductor device 1 more appropriately. This makes it possible to further increase the carrier density of the two-dimensional electron gas layer 2DEG formed in the channel layer 14.

The barrier layer 17 includes a nitride semiconductor having a larger bandgap than the bandgap of the channel layer 14. The barrier layer 17 is provided on the second spacer layer 16. The barrier layer 17 allows a canier to accumulate in the channel layer 14, in a region near the barrier layer 17 by spontaneous polarization or piezoelectric polarization. In the semiconductor device 1, this allows the two-dimensional electron gas layer 2DEG having high mobility and high carrier concentration to be formed in a region adjacent to the interface K45 in the channel layer 14.

The barrier layer 17 includes Alₓ₁In_{y1}Ga_{(1-x1-y1)}N (0<x1<1, 0<y1<1), which is an epitaxially grown nitride semiconductor. Here, x1>0.7, and y1<0.3 may also be satisfied. For example, the barrier layer 17 may include undoped u-Alₓ₁In₍₁₋ₓ₁₎N with no added impurity. In such a case, the barrier layer 17 allows a lattice mismatch with GaN to be reduced, thus making it possible to obtain a crystal with high single crystallinity.

For example, it is possible to control the carrier density of the two-dimensional electron gas layer 2DEG by the bandgap profile of each layer from the barrier layer 17 to the channel layer 14. One factor that determines the carrier density of the two-dimensional electron gas layer 2DEG is a height of a conduction band minimum of the barrier layer 17.

For example, the higher the Al composition of each layer, the greater the polarization of each layer. This results in a greater slope of the conduction band minimum. In addition, the greater the thickness of each layer, the greater the height of the conduction band minimum. Thus, it is possible to increase the carrier density of the two-dimensional electron gas layer 2DEG by appropriately controlling the thickness and composition of each layer from the barrier layer 17 to the channel layer 14 and controlling the height of the conduction band minimum of the barrier layer 17.

For example, the barrier layer 17 includes Alₓ₁In₍₁₋ₓ₁)N (0<x1<1, 0<y1<1) having a higher percentage of Al composition than the Alₓ₅In_{y5}Ga_{(1-x5-y5)}N included in the second spacer layer 16. In other words, the barrier layer 17 includes a nitride semiconductor satisfying x5<x1 with respect to the second spacer layer 16, thereby allowing a greater polarization to be obtained. This makes it possible to further increase the carrier concentration of the two-dimensional electron gas layer 2DEG. For example, as a result of the barrier layer 17 including a nitride semiconductor in which x1 is greater than 0.7, it is possible to obtain a greater polarization. This allows a higher carrier concentration of the two-dimensional electron gas layer 2DEG. For example, the barrier layer 17 includes AlInN. The barrier layer 17 may include AlInGaN, AlGaN, or AlN. In a case where the barrier layer 17 includes AlInGaN, it is possible to obtain a constant design margin for the bandgap and strain. Furthermore, as a result of the barrier layer 17 including Ga, the single crystallinity of the barrier layer 17 is improved.

It is preferable for the barrier layer 17 to have a thickness of 2.0 nm or more and 20 nm or less. In such a case, it is possible for the barrier layer 17 to control the bandgap profile of the semiconductor device 1 more appropriately. This makes it possible to further increase the carrier density of the two-dimensional electron gas layer 2DEG formed in the channel layer 14. It should be noted that the thickness of the barrier layer 17 here is a thickness not including the intermediate layer 18. Furthermore, it is more preferable for the barrier layer 17 to have a thickness of 3.0 nm or more and 10 nm or less.

In the present embodiment, the barrier layer 17 includes therein the intermediate layer 18 separating the barrier layer 17 into a lower layer (first barrier layer 17A) and an upper layer (second barrier layer 17B). The intermediate layer 18 includes Alₓ₂In_{y2}Ga_{(1-x2-y2)}N (0≤x2≤1, 0≤y2<1), which is an epitaxially grown nitride semiconductor, and satisfies (1−x1−y1)<(1−x2−y2). Furthermore, the Alₓ₂In_{y2}Ga_{(1-x2-y2)}N (0≤x2≤1, 0≤y2<1) included in the intermediate layer 18 satisfies x2<x1 with respect to Alₓ₁In_{y1}Ga_{(1-x1-y1)}N (x5<x1≤1, 0≤y1<1), which is a nitride semiconductor included in the barrier layer 17. Furthermore, the Alₓ₂In_{y2}Ga_{(1-x2-y2)}N (0≤x2≤1, 0≤y2<1) included in the intermediate layer 18 also satisfies 1−x2−y2>0.01. For example, the intermediate layer 18 includes GaN. Because the intermediate layer 18 including Ga has excellent single crystallinity and morphology, the crystallinity of the barrier layer 17 is improved by inserting the intermediate layer 18 having a higher Ga composition than the barrier layer 17 into the barrier layer 17.

It is preferable for the intermediate layer 18 to have a thickness of 0.26 nm or more and 2.0 nm or less. In a case where the thickness of the intermediate layer 18 is greater than 2.0 mu, the density of the two-dimensional electron gas concentration in the channel layer 14 decreases, resulting in carrier generation in the intermediate layer 18.

The barrier layer 17 including AlInN is particularly likely to oxidize due to the high composition ratio of Al. To suppress such oxidation, it is sufficient to provide the protective layer 19 over the barrier layer 17. The protective layer 19 protects a surface of the barrier layer 17 from an impurity such as a chemical or various types of ions while maintaining the surface of the barrier layer 17 in a preferred state, thus making it possible to suppress deterioration of an operating characteristic of the semiconductor device 1. The protective layer 19 includes, for example, Alₓ₃In_{y3}Ga_{(1-x3-y3)}N (0≤x3<1, 0≤y3<1), which is an epitaxially grown nitride semiconductor. It should be noted that in relation to the nitride semiconductor included in the barrier layer 17, it is sufficient to satisfy (1−x1−y1)<(1−x3−y3). For this reason, the protective layer 19 includes, for example, GaN. The protective layer 19 may include AlInGaN, AlGaN, or InGaN. GaN has the highest single crystallinity. InGaN facilitates n-type contact. By choosing a lower Al composition than the barrier layer 17, AlInGaN and AlGaN make it possible to obtain a mixed crystal having a larger bandgap than GaN and InGaN while functioning as a protective layer. Having a large bandgap gives an advantage in obtaining a high two-dimensional electron gas concentration.

The gate electrode G, the source electrode S, and the drain electrode D each include a conductive material. The gate electrode G, the source electrode S, and the drain electrode D are each provided on the semiconductor layer. The gate electrode G is provided between the source electrode S and the drain electrode D. The gate electrode G is a Schottky gate, which forms a Schottky junction by contacting the nitride semiconductor included in the protective layer 19 not via the insulating film Z. The gate electrode G may, for example, have a two-layer configuration in which a Ni(nickel) layer and an Au (gold) layer are sequentially stacked on the protective layer 19. In addition, the source electrode S and the drain electrode D may be provided, for example, to have a configuration in which a Ti (titanium) layer, an Al (aluminum) layer, a Ni (nickel) layer, and an Au (gold) layer are sequentially stacked on the protective layer 19.

The insulating film Z includes an insulating material. The insulating film Z is provided to cover a region which is included in the protective layer 19 and which is not covered by any of the gate electrode G, the source electrode S, and the drain electrode D. The insulating film Z includes, for example, Al₂O₃ (aluminum oxide), SiO₂ (silicon dioxide), Si₃N₄ (silicon nitride), HfO₂ (hafnium oxide), or the like as a constituent material. The insulating film Z may be a monolayer film including the constituent material described above or a multilayer film in which a plurality of layers each including the constituent material described above is stacked.

### 1-2. Method of Manufacturing Semiconductor Device

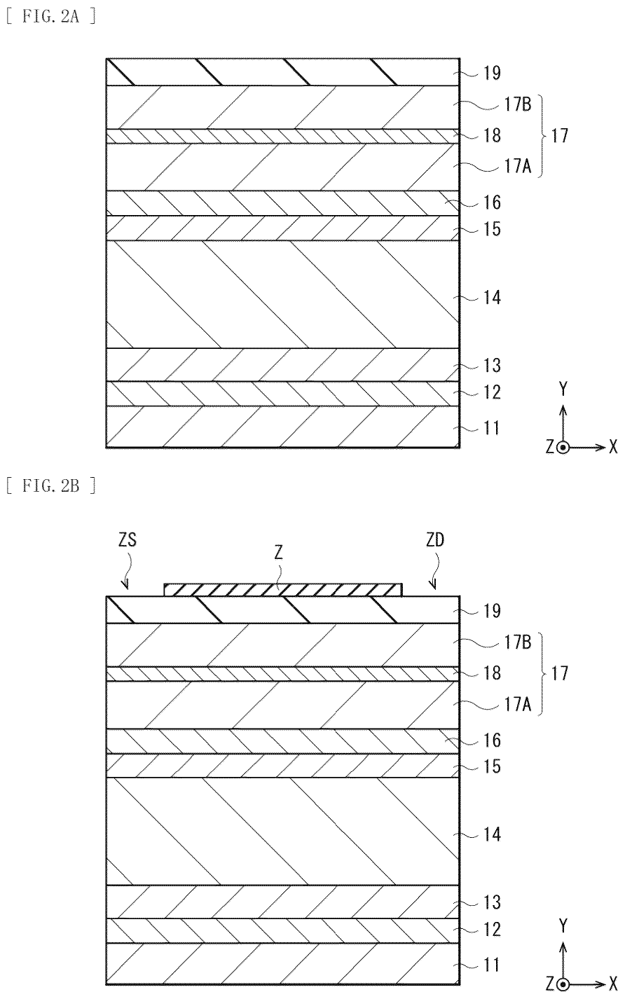

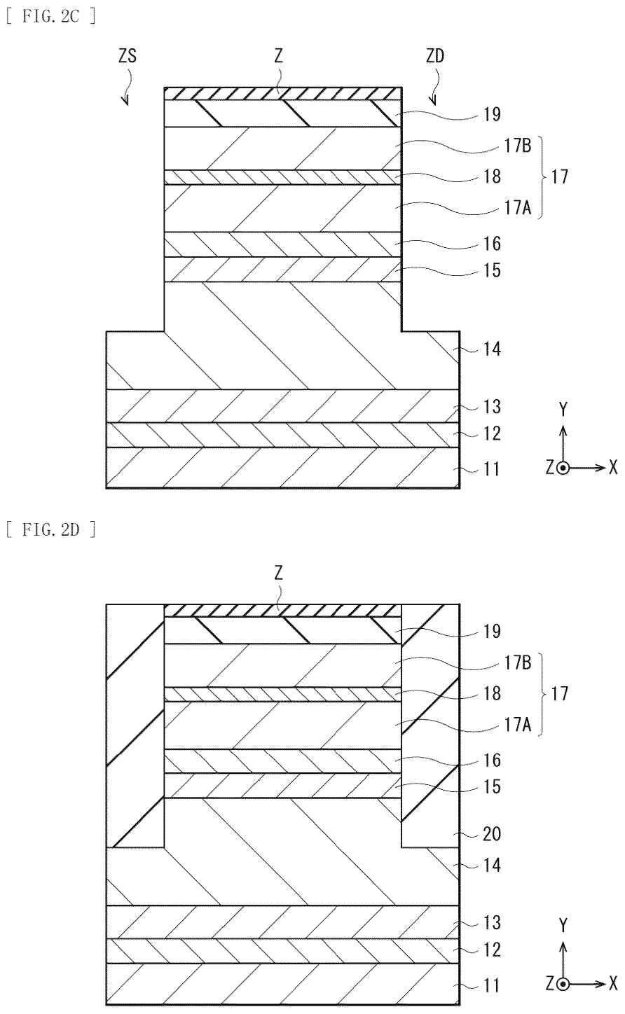

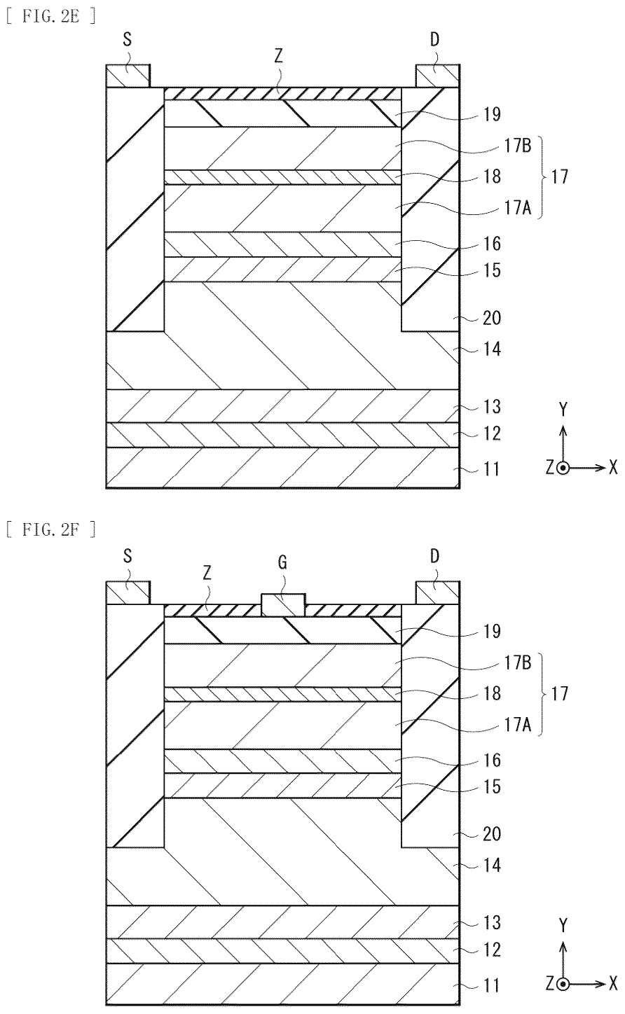

Next, an example of a method of manufacturing the semiconductor device 1 according to the present embodiment is described with reference to FIGS. 2A to 2F. FIGS. 2A to 2F are each a schematic cross-sectional view illustrating each process in the method of manufacturing the semiconductor device 1.

First, as illustrated in FIG. 2A, for example, the first buffer layer 12, the second buffer layer 13, the channel layer 14, the first spacer layer 15, the second spacer layer 16, the first barrier layer 17A, the intermediate layer 18, the second barrier layer 17B, and the protective layer 19 are epitaxially grown sequentially on the substrate 11. It should be noted that for the substrate 11, it is possible to use a Si substrate, a sapphire substrate, a SiC substrate, a GaN substrate, an AlN substrate, a GaAs substrate, a ZnO substrate, a ScAlMgO substrate or the like. However, the following describes a case where a Si substrate is used as an example.

For example, first, a Si substrate having a (111) place as a main surface is introduced into a MOCVD (metal organic chemical vapor deposition) apparatus, and thermal cleaning is performed at 1000° C. for about 10 minutes. Then, the first buffer layer 12 is formed by epitaxially growing AlN to a thickness of about 100 mu to 300 nm at about 700° C. to 1100° C.

Next, the second buffer layer 13 is formed on the first buffer layer 12, for example, by epitaxially growing AlGaN having an Al composition of about 0.20 at about 900° C. to 1100° C. to a thickness of 100 nm to 500 nm.

Subsequently, the channel layer 14 is formed on the second buffer layer 13, for example, by epitaxially growing GaN at about 900° C. to 1100° C. to a thickness of 500 nm to 2000 nm.

Then, the first spacer layer 15 is formed on the channel layer 14, for example, by epitaxially growing AlN at 900° C. to 1100° C. to a thickness of about 0.5 nm to 1.5 nm.

Next, the second spacer layer 16 is formed on the first spacer layer 15, for example, by epitaxially growing GaN at 900° C. to 1100° C. to about 0.5 mu to 1.5 nm.

Subsequently, the first barrier layer 17A is formed, for example, by epitaxially growing AlInN at 700° C. to 900° C. to about 1 nm to 10 nm. Next, the intermediate layer 18 is formed on the first barrier layer 17A, for example, by epitaxially growing GaN at 900° C. to 1100° C. to about 0.26 nm to 2.0 nm. Then, the second barrier layer 17B is formed on the intermediate layer 18, for example, by epitaxially growing AlInN at 700° C. to 900° C. to about 1 nm to 10 nm.

Furthermore, the protective layer 19 is formed on the barrier layer 17, for example, by epitaxially growing GaN at 700° C. to 1000° C. to about 1 mu to 5 nm.

Next, as illustrated in FIG. 2B, the insulating film Z is formed by forming a film of SiN, SiO₂, Al₂O₃, or the like on the protective layer 19. Subsequently, the insulating film Z is selectively removed using a resist pattern having an opening in a region corresponding to each of the source electrode S and the drain electrode D. In other words, only a portion of the insulating film Z, which is a region in which each of the source electrode S and the drain electrode D is to be formed, is selectively removed. As a result, an opening ZS and an opening ZD are formed to expose a portion of an upper surface of the protective layer 19.

Subsequently, as illustrated in FIG. 2C, the opening ZS and the opening ZD are extended to a middle of the channel layer 14 by dry etching using the insulating film Z as a mask.

Next, as illustrated in FIG. 2D, a GaN layer 20 having an n-type conductivity is grown, for example, by MOCVD, sputtering, or the like. At this time, it is possible to use Si or Ge (germanium) as a dopant. As a result of providing the GaN layer 20 in contact with the channel layer 14, it is possible to obtain a device having a low on-resistance (Ron).

Subsequently, as illustrated in FIG. 2E, the source electrode S and the drain electrode D are each formed by selectively stacking a Ti layer, an Al layer, a Ni layer, and an Au layer sequentially on an upper surface of the GaN layer 20.

Then, as illustrated in FIG. 2F, the insulating film Z is selectively removed using a resist pattern having an opening in a region corresponding to the gate electrode G. In other words, only a portion of the insulating film Z, which is a region in which the gate electrode G is to be formed, is selectively removed. As a result, an opening ZG is formed to expose a portion of the upper surface of the protective layer 19. Then, the gate electrode G is formed by selectively stacking a Ni layer and an Au layer sequentially on the exposed upper surface of the protective layer 19.

Following the above process, it is possible to form the semiconductor device 1 according to the present embodiment illustrated in FIG. 1.

### 1-3. Workings and Effects

A nitride semiconductor including AlInGaN is a material that enables light emission to be obtained from an ultraviolet region to an infrared region by controlling the composition ratio of Al, Ga, and In. After a commercialization of a blue light-emitting diode (LED) using InGaN in a light-emitting layer, an LED and a semiconductor laser (LD) from an ultraviolet region to a green region are now in practical use. These light-emitting devices are used for illumination, backlighting of an LCD panel, a projection light source, etc.

Meanwhile, research and development of a HEMT using a nitride semiconductor has been actively conducted in recent years. A nitride semiconductor has a larger bandgap than Si, GaAs, or the like, and has a polarization characteristic unique to a hexagonal crystal. For this reason, the HEMT using a nitride semiconductor is expected to be a transistor that allows low resistance, high breakdown voltage, and high-speed operation.

Specifically, the HEMT is expected to be applied to a power device or a radio frequency (RF) device or the like. For example, a HEMT using AlGaN in a barrier layer is in practical use in a base station for satellite communications or wireless communications. A HEMT using AlInN in the barrier layer makes it possible to obtain an even higher two-dimensional electron gas concentration than the HEMT using AlGaN in the barrier layer, and thus is expected to allow even higher power.

In a HEMT in which a barrier layer including AlInN is directly stacked on a channel layer including GaN, there is a high scattering probability due to a fluctuation in an In composition of AlInN at an AlInN/GaN interface. Therefore, in the HEMT in which the barrier layer including AlInN is directly stacked on the channel layer including GaN, the mobility of the two-dimensional electron gas is more than one order lower than a value predicted by theoretical calculation.

It has been found that inserting a spacer layer including AlN by about 1 nm between the channel layer including GaN and the barrier layer including AlInN makes it possible to suppress scattering due to AlInN, allowing a significant improvement in mobility.

In addition, a HEMT having a three-layer configuration (GaN/AlN/AlInN) that includes a channel layer including GaN, a spacer layer including AlN, and a barrier layer including AlInN has an issue of low process resistance, such as low heat resistance or chemical resistance, or being subject to etching damage, compared with a HEMT having a two-layer configuration (GaN/AlGaN) that includes a channel layer including GaN and a barrier layer including AlGaN. Such difficulty limits a degree of freedom of a process flow and a process condition, thus causing a difficulty in practical application.

Furthermore, an AlInN mixed crystal is a ternary mixed crystal including AlN and InN, but there is a significant difference in physical property value such as saturation vapor pressure between AlN and InN, and has low miscibility. For this reason, AlInN has lower single crystallinity, higher impurity concentration, and more difficulty in obtaining a smooth surface than GaN, AlGaN, or the like. These properties are likely to cause oxidation or etching in the HEMT that includes a barrier layer including AlInN in an outermost layer at the time of processing. In addition, after heat treatment, a sheet resistance tends to deteriorate due to a decrease in the two-dimensional electron gas concentration or a decrease in mobility, making it difficult to obtain a device characteristic expected from a material property. Furthermore, it is also difficult to manufacture a device with high reliability. In addition, for a Schottky gate type HEMT, there is an issue of large off-leakage current.

To address these issues, a HEMT has been proposed in which an outermost surface of the barrier layer including AlInN is protected by a protective layer including GaN. However, even the HEMT in which the protective layer is provided is not sufficient to address a fundamental cause of the low crystallinity of AlInN. In addition, the protective layer is an unnecessary layer in terms of a function of an RF device. Therefore, providing the protective layer increases a thickness of an epitaxial growth layer, which is an upper layer of the two-dimensional electron gas, thus reducing an alternating conductance (gm) and a high frequency characteristic.

In contrast, in the semiconductor device 1 according to the present embodiment, the intermediate layer 18 including a nitride semiconductor that includes Alₓ₂In_{y2}Ga_{(1-x2-y2)}N (0≤x2<1, 0≤y2<1) and satisfies (1−x1−y1)<(1−x2−y2) is provided within the barrier layer 17 including a nitride semiconductor Alₓ₁In_{y1}Ga_{(1-x1-y1)}N (0<x1<1.0<y1<1)) having a larger bandgap than that of the channel layer 14, thus improving the crystallinity of the barrier layer 17.

Thus, the semiconductor device 1 makes it possible to improve heat resistance.

In addition, the barrier layer 17 having excellent crystallinity makes it possible to obtain an effect of suppressing surface oxidation of the barrier layer 17. In other words, it is possible to reduce the thickness of the protective layer 19, and thus to obtain a high gm or a high frequency characteristic without deteriorating the sheet resistance of the two-dimensional electron gas. Furthermore, although the semiconductor device 1 has a Schottky-type gate configuration, the improved crystallinity of the barrier layer 17 makes it possible to reduce what is called an off-leakage current compared with a semiconductor device having a configuration without the intermediate layer 18.

Next, Modification Examples 1 to 5, examples, and application examples of the present disclosure are described. It should be noted that components corresponding to those of the semiconductor device of the embodiment described above are denoted by the same reference numerals, and the description thereof is omitted.

### 2. MODIFICATION EXAMPLES

### 2-1. Modification Example 1

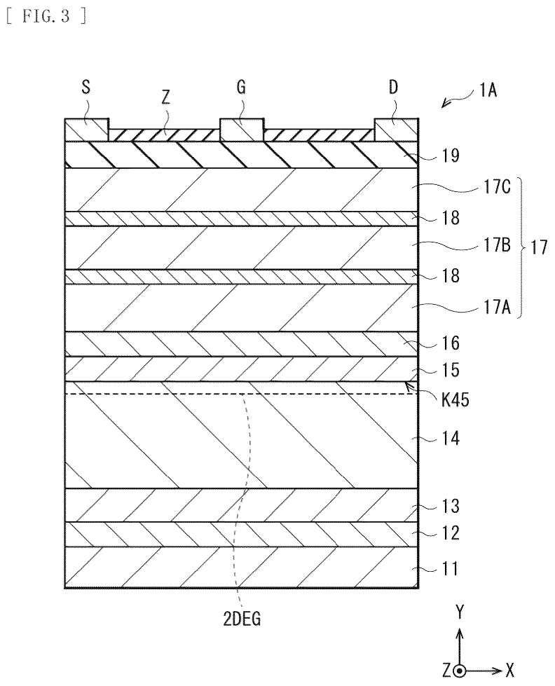

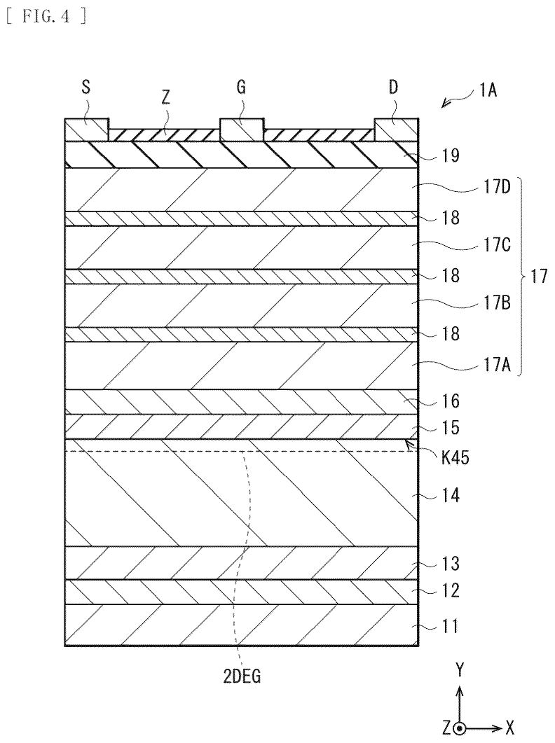

FIG. 3 schematically illustrates an example of a cross-sectional configuration of a semiconductor device (semiconductor device 1A) according to Modification Example 1 of the present disclosure. FIG. 4 schematically illustrates another example of the cross-sectional configuration of the semiconductor device 1A according to Modification Example 1 of the present disclosure.

In the above embodiment, the intermediate layer 18 dividing the barrier layer 17 into the first barrier layer 17A and the second barrier layer 17B is inserted into the barrier layer 17. In contrast, in the semiconductor device 1A in the present modification example, a plurality of intermediate layers dividing the barrier layer 17 into a plurality of layers in a stacking direction (Y-axis direction) is inserted into the barrier layer 17.

In other words, the semiconductor device 1A has a stacked configuration in which the substrate 11, the first buffer layer 12, the second buffer layer 13, the channel layer 14, the first spacer layer 15, the second spacer layer 16, the barrier layer 17, and, for example, two intermediate layers 18 dividing the barrier layer 17 into, for example, three layers (a first barrier layer 17A, a second barrier layer 17B, and a third barrier layer 17C), and the protective layer 19 are stacked in sequence. In addition, the semiconductor device 1A has a stacked configuration in which the substrate 11, the first buffer layer 12, the second buffer layer 13, the channel layer 14, the first spacer layer 15, the second spacer layer 16, the barrier layer 17, and, for example, three intermediate layers 18 diving the barrier layer 17 into, for example, four layers (the first barrier layer 17A, the second barrier layer 17B, the third barrier layer 17C, and a fourth barrier layer 17D), and the protective layer 19 are stacked in sequence. Except for these points, the semiconductor device 1A has a configuration substantially similar to that of the semiconductor device 1.

Also in the semiconductor device 1A of the present modification example, a plurality of intermediate layers 18 each including a nitride semiconductor that includes Alₓ₂In_{y2}Ga_{(1-x2-y2)}N (0≤x2<1, 0≤y2<1) and satisfies (1−x1−y1)<(1−x2−y2) is provided within the barrier layer 17 including a nitride semiconductor (Alₓ₁In_{y1}Ga_{(1-x1-y1)}N (0<x1<1, <y1<1)) having a larger bandgap than the bandgap of the channel layer 14, thus improving the crystallinity of the barrier layer 17. Thus, the semiconductor device 1 makes it possible to improve heat resistance, as in the above embodiment. In addition, it is possible to obtain a high gm and a high frequency characteristic without deteriorating the sheet resistance of the two-dimensional electron gas. Furthermore, although the semiconductor device 1 has a Schottky-type gate configuration, the improved crystallinity of the barrier layer 17 makes it possible to reduce what is called an off-leakage current compared with a semiconductor device having a configuration without the intermediate layer 18.

### 2-2. Modification Example 2

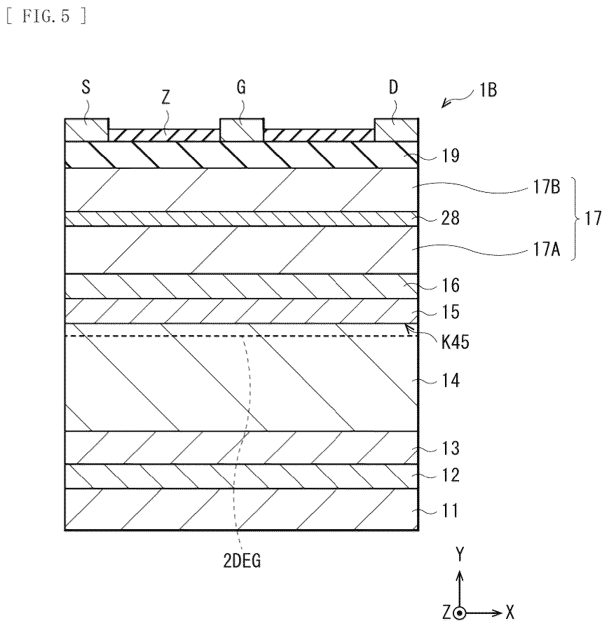

FIG. 5 schematically illustrates an example of a cross-sectional configuration of a semiconductor device (semiconductor device 1B) according to Modification Example 2 of the present disclosure.

In the above embodiment, as the nitride semiconductor including Alₓ₂In_{y2}Ga_{(1-x2-y2)}N (0≤x2≤1, 0≤y2<1), the intermediate layer 18 including GaN is inserted into the barrier layer 17. In contrast, in the semiconductor device 1B in the present modification example, as the nitride semiconductor including Alₓ₂In_{y2}Ga_{(1-x2-y2)}N (0≤x2≤1, 0≤y2<1), an intermediate layer 28 including AlGaN or AlInGaN having a greater Ga composition than the Ga composition of the barrier layer 17 is inserted into the barrier layer 17. For an AlGaN mixed crystal or AlInGaN mixed crystal, it is preferable that the Ga composition be at least 1% or more, and particularly preferable that the Ga composition be 30% or more. Except for this point, the semiconductor device 1B has a configuration substantially similar to that of the semiconductor device 1.

Also in the semiconductor device 1B of the present modification example, the intermediate layer 28 including a nitride semiconductor that includes Alₓ₂In_{y2}Ga_{(1-x2-y2)}N (0≤x2<1, 0≤y2<1) and satisfies (1−x1−y1)<(1−x2−y2) is provided within the barrier layer 17 including a nitride semiconductor (Alₓ₁In_{y1}Ga_{(1-x1-y1)}N (0<x1<1, 0<y1<1)) having a larger bandgap than the bandgap of the channel layer 14, thus improving the crystallinity of the barrier layer 17. Thus, the semiconductor device 1 makes it possible to improve the heat resistance, as in the above embodiment. In addition, it is possible to obtain a high gm and a high frequency characteristic without deteriorating the sheet resistance of the two-dimensional electron gas. Furthermore, although the semiconductor device 1 has a Schottky-type gate configuration, the improved crystallinity of the barrier layer 17 makes it possible to reduce what is called an off-leakage current compared with a semiconductor device having a structure without the intermediate layer 28.

### 2-3. Modification Example 3

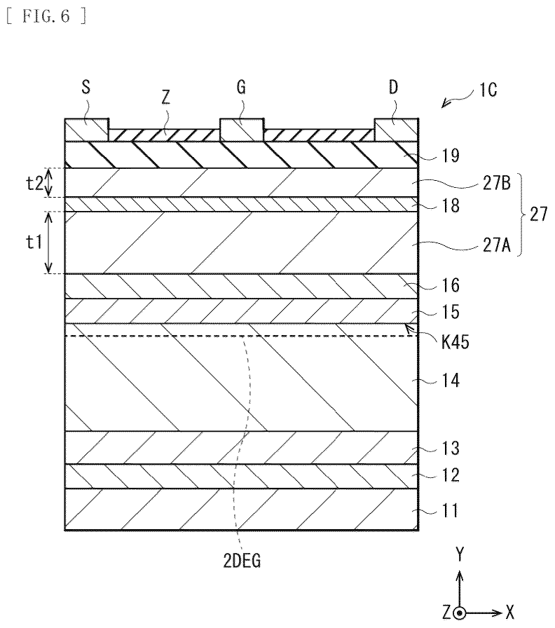

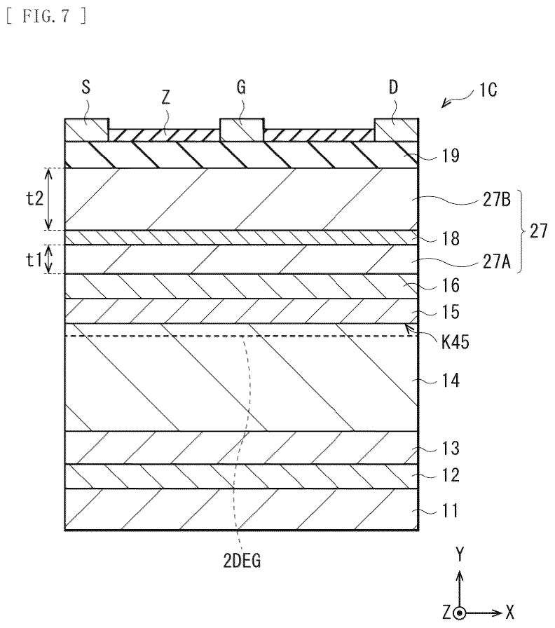

FIG. 6 schematically illustrates an example of a cross-sectional configuration of a semiconductor device (semiconductor device 1C) according to Modification Example 3 of the present disclosure. FIG. 7 schematically illustrates another example of the cross-sectional configuration of the semiconductor device 1C according to Modification Example 3 of the present disclosure.

In the above embodiment, the intermediate layer 18 is inserted at a position at which the barrier layer 17 is divided into the first barrier layer 17A and the second barrier layer 17B each having approximately the same thickness. In contrast, in the semiconductor device 1C in the present modification example, the intermediate layer 18 is inserted at a position at which a lower layer (first barrier layer 27A) has a greater thickness than an upper layer (second barrier layer 27B) as illustrated in FIG. 6, and the upper layer (second barrier layer 27AB) has a greater thickness than the lower layer (first barrier layer 27A) as illustrated in FIG. 7. Except for these points, the semiconductor device 1C has a configuration substantially similar to that of the semiconductor device 1.

Also in the semiconductor device 1C of the present modification example, the intermediate layer 18 including a nitride semiconductor that includes Alₓ₂In_{y2}Ga_{(1-x2-y2)}N (0≤x2<1, 0≤y2<1) and satisfies (1−x1−y1)<(1−x2−y2) is provided within the barrier layer 27 including a nitride semiconductor (Alₓ₁In_{y1}Ga_{(1-x1-y1)}N (0<x1<1, 0<y1<1)) having a larger bandgap than the bandgap of the channel layer 14, thus improving the crystallinity of the barrier layer 27. Thus, the semiconductor device 1 makes it possible to improve the heat resistance, as in the above embodiment. In addition, it is possible to obtain a high gm and a high frequency characteristic without deteriorating the sheet resistance of the two-dimensional electron gas. Furthermore, although the semiconductor device 1 has a Schottky-type gate configuration, the improved crystallinity of the barrier layer 27 makes it possible to reduce what is called an off-leakage current compared with a semiconductor device having a configuration without the intermediate layer 28.

### 2-4. Modification Example 4

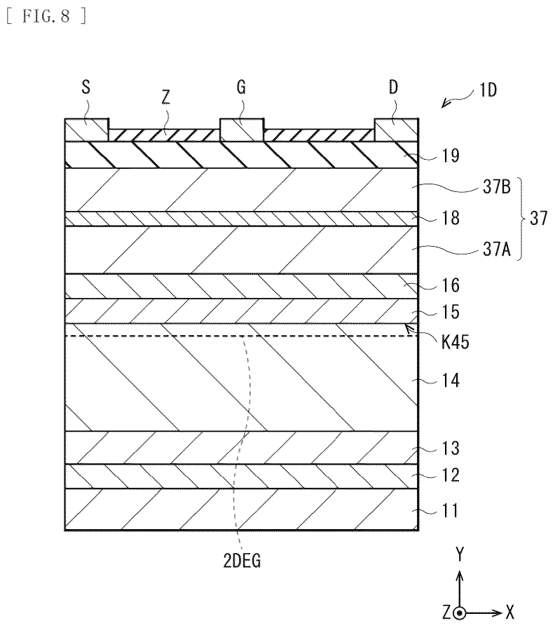

FIG. 8 schematically illustrates an example of a cross-sectional configuration of a semiconductor device (semiconductor device 1D) according to Modification Example 4 of the present disclosure.

In the above embodiment, the intermediate layer 18 is inserted into the barrier layer 17 including AlInN as a nitride semiconductor that includes (Alₓ₁In_{y1}Ga_{(1-x1-y1)}N (0<x1<1, 0<y1<1)). In contrast, in the semiconductor device 1D in the present modification example, one of a first barrier layer 37A or a second barrier layer 37B separated by the intermediate layer 18 including AlInGaN as a nitride semiconductor that includes Alₓ₁In_{y1}Ga_{(1-x1-y1)}N (0<x1<1, 0<y1<1). Except for this point, the semiconductor device 1D has a configuration substantially similar to that of the semiconductor device 1.

Also in the semiconductor device 1D of the present modification example, the intermediate layer 18 including a nitride semiconductor that includes Alₓ₂In_{y2}Ga_{(1-x2-y2)}N (0≤x2<1, 0≤y2<1) and satisfies (1−x1−y1)<(1−x2−y2) is provided within a barrier layer 37 including a nitride semiconductor (Alₓ₁In_{y1}Ga_{(1-x1-y1)}N (0<x1<1, 0<y1<1)) having a larger bandgap than the bandgap of the channel layer 14, thus improving the crystallinity of the barrier layer 37. Thus, the semiconductor device 1 makes it possible to improve the heat resistance, as in the above embodiment. In addition, it is possible to obtain a high gm and a high frequency characteristic without deteriorating the sheet resistance of the two-dimensional electron gas. Furthermore, although the semiconductor device 1 has a Schottky-type gate configuration, the improved crystallinity of the barrier layer 37 makes it possible to reduce what is called an off-leakage current compared with a semiconductor device having a configuration without the intermediate layer 18.

### 2-5. Modification Example 5

FIG. 9 schematically illustrates an example of a cross-sectional configuration of a semiconductor device (semiconductor device 1E) according to Modification Example 5 of the present disclosure.

In the above embodiment, the intermediate layer 18 is inserted into the barrier layer 17 including AlInN as a nitride semiconductor that includes (Alₓ₁In_{y1}Ga_{(1-x1-y1)}N (0<x1<1, 0<y1<1)). In contrast, in the semiconductor device 1E in the present modification example, an AlInN mixed crystal, which is a nitride semiconductor including Alₓ₁In_{y1}Ga_{(1-x1-y1)}N (0<x1<1, 0<y1<1) and is included in a first barrier layer 47A and a second barrier layer 47B separated by the intermediate layer 18, has an Al composition different from each other. Except for this point, the semiconductor device 1E has a configuration substantially similar to that of the semiconductor device 1.

Also in the semiconductor device 1E of the present modification example, the intermediate layer 18 including a semiconductor that includes Alₓ₂In_{y2}Ga_{(1-x2-y2)}N (0≤x2<1, 0≤y2<1) and satisfies (1−x1−y1)<(1−x2−y2) is provided within a barrier layer 47 including a nitride semiconductor (Alₓ₁In_{y1}Ga_{(1-x1-y1)}N (0<x1<1, 0<y1<1)) having a larger bandgap than the bandgap of the channel layer 14, thus improving the crystallinity of the barrier layer 47. Thus, the semiconductor device 1 makes it possible to improve the heat resistance, as in the above embodiment. In addition, it is possible to obtain a high gin and a high frequency characteristic without deteriorating the sheet resistance of the two-dimensional electron gas. Furthermore, although the semiconductor device 1 has a Schottky-type gate configuration, the improved crystallinity of the barrier layer 47 makes it possible to reduce what is called an off-leakage current compared with the semiconductor device having a configuration without the intermediate layer 18.

### 3. EXAMPLES

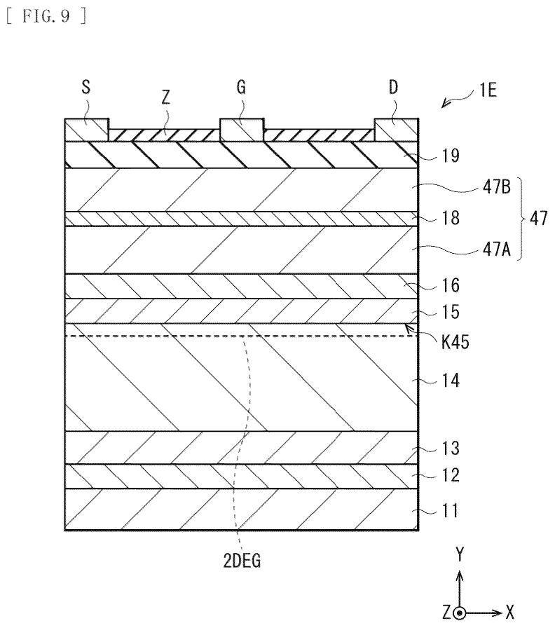

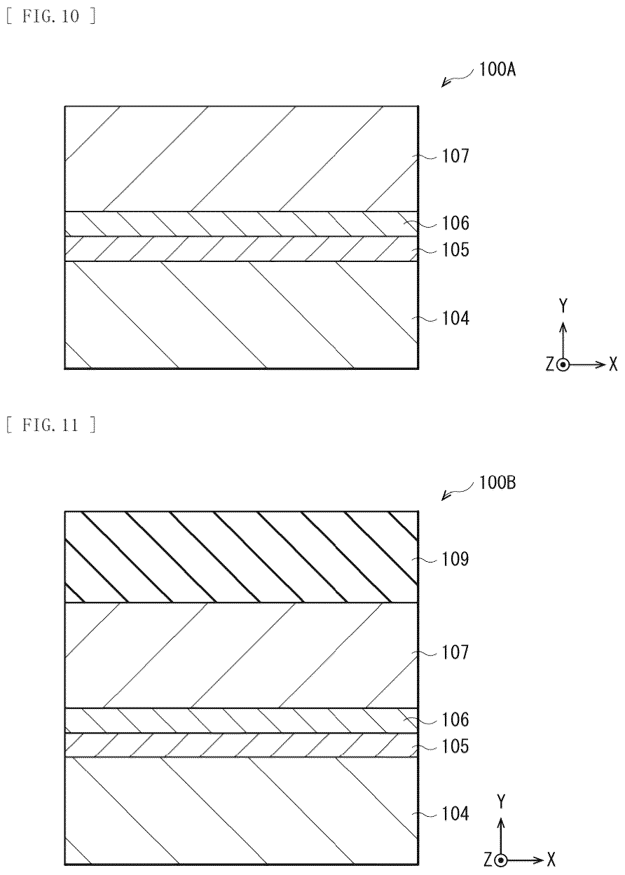

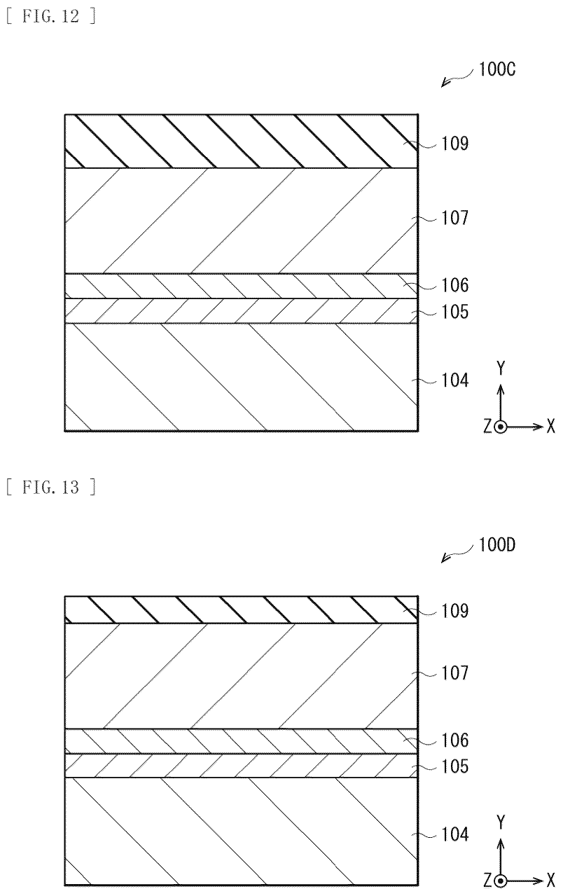

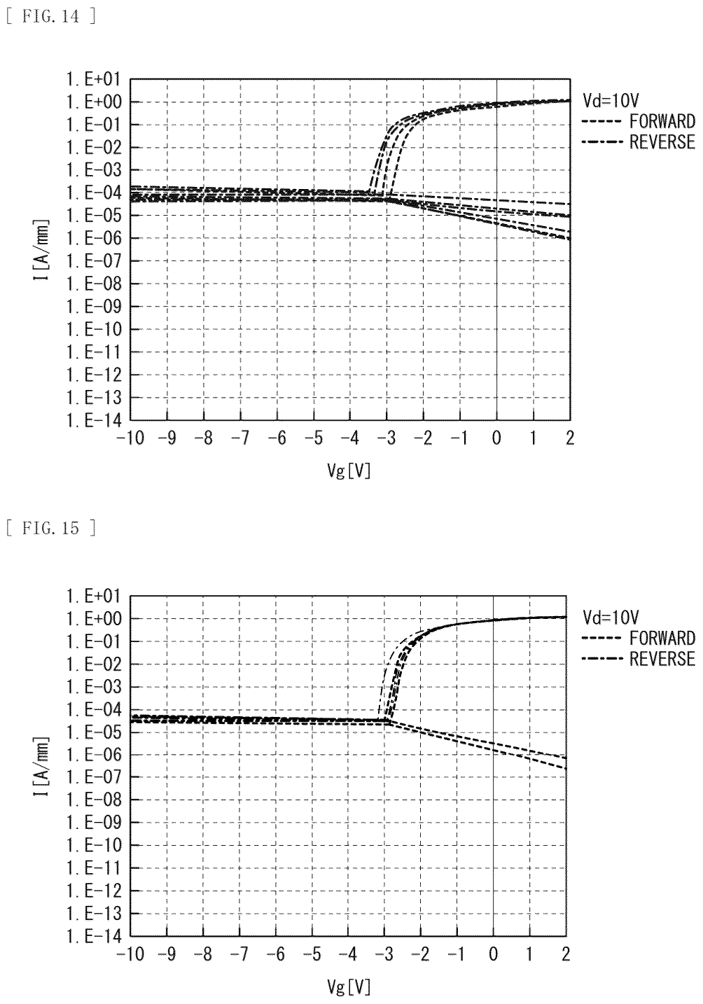

FIGS. 10 to 13 each schematically illustrate a cross-sectional configuration of a general semiconductor device (semiconductor device 100A, 100B, 100C, or 100D) as a reference example. A sample of the semiconductor device 1 as Example illustrated in FIG. 1 and a sample of each of the semiconductor devices 100A, 100B, 100C, and 100D as a reference example were prepared, and a heat resistance, off-leakage current, barrier layer oxidation suppression, and gm characteristic thereof were evaluated.

### [Evaluation of Heat Resistance]

### Example

The semiconductor device 1 illustrated in FIG. 1 was tested for heat resistance. Specifically, a sample in which the channel layer 14, the first spacer layer 15, the second spacer layer 16, the barrier layer 17, the intermediate layer 18 provided within the barrier layer 17, and the protective layer 19 of the semiconductor device 1 illustrated in FIG. 1 are stacked was prepared, and the sample was annealed at 900° C. for 2 minutes under a nitrogen atmosphere, to compare a change in sheet resistance before and after the annealing. Here, the sheet resistance of the two-dimensional electron gas layer 2DEG formed in the channel layer was measured by an eddy current method.

It should be noted that in the semiconductor device 1 as the sample of Example, the channel layer 14 includes GaN having a film thickness of 200 mu. The first spacer layer 15 includes AlN having a film thickness of 1.0 nm. The second spacer layer 16 includes GaN having a film thickness of 1.0 nm. For the barrier layer 17, the first barrier layer 17A includes AlInN having a film thickness of 1.8 nm, and the second barrier layer 17B includes AlN having a film thickness of 1.8 nm. The intermediate layer 18 includes GaN having a film thickness of 0.25 nm. The protective layer 19 includes GaN having a film thickness of 2.5 nm.

### Reference Examples 1 to 4

For comparison, a sample of each of the semiconductor devices 100A, 100B, 100C, and 100D as Reference Examples 1 to 4 was prepared and tested for heat resistance in a similar manner to Example. The sample of the semiconductor device 100A as Reference Example 1 has the same configuration as the sample of the semiconductor device 1 of Example, except that the barrier layer 107 includes AlInN having a film thickness of 4 nm, and neither the intermediate layer 108 nor the protective layer 109 is included. The sample of the semiconductor device 100B as Reference Example 2 has the same configuration as the sample of the semiconductor device 1 of Example, except that the barrier layer 107 includes AlInN having a film thickness of 4 nm, the protective layer 109 includes GaN having a film thickness of 2.5 nm, and the intermediate layer 108 is not included. The sample of the semiconductor device 100C as Reference Example 3 has the same configuration as the sample of the semiconductor device 1 of Example, except that the barrier layer 107 includes AlInN having a film thickness of 4 nm, the protective layer 109 includes GaN having a film thickness of 1.0 nm, and the intermediate layer 108 is not included. The sample of the semiconductor device 100D as Reference Example 4 has the same configuration as the sample of the semiconductor device 1 of Example, except that the barrier layer 107 includes AlInN having a film thickness of 4 nm, the protective layer 109 includes GaN having a film thickness of 0.5 n, and the intermediate layer 108 is not included.

In Example and Reference Examples 1 to 4, the change in sheet resistance before and after annealing was 27% in Example, 154% in Reference Example 1, 24% in Reference Example 2, 42% in Reference Example 3, and 40% in Reference Example 4.

From this result, it was found that in a case where the thickness of the protective layer 109 is varied, the heat resistance improves as the thickness increases. However, as described above, for the protective layers 19 and 109 including GaN, the high frequency characteristic decreases as the thickness increases. Therefore, it is desirable that the thickness of the protective layers 19 and 109 be as small as possible. In the semiconductor device 1 of Example, the heat resistance was improved compared with Reference Example 4 having the same thickness of 0.5 mu as the protective layer 19, and the heat resistance thereof was equivalent to that of Reference Example 2 including the protective layer 109 having a thickness five times greater (2.5 nm).

### [Evaluation of Off-Leak Current]

For Reference Example 4 and Example, an Id (drain current)−Vg (gate voltage) characteristic was measured, and the result is shown in FIG. 14 (Reference Example 4) and 15 (Example). It was found that the sample of Example enabled a reduction of the off-leakage current by about 0.6 times compared with that of the sample of Reference Example 4. This is considered to be due to the improved crystallinity of the barrier layer 17 in the semiconductor device 1 of Example as compared with that of the semiconductor device 100D of Reference Example 4.

### [Evaluation of Oxidation Suppression]

Oxygen contamination from an outermost layer in each sample of Example, Reference Example 1, and Reference Example 4 was analyzed by transmission electron microscopy (TEM) and energy dispersive X-ray analysis (EDX). As a result, oxygen contamination of 4 nm, that is, across an entire barrier layer, was observed in the sample of Reference Example 1 that does not include the protective layer 109, and oxygen contamination to a depth of 1.5 nm from an upper surface of the barrier layer 104 was observed in the sample of Reference Example 4 that includes the protective layer 109 having a thickness of 0.5 nm. In contrast, in the sample of Example, oxygen contamination was observed to a depth of 0.5 nm from an upper surface of the barrier layer 104. In addition, a similar result was obtained using electron energy loss spectroscopy (EELS). This indicates that the semiconductor device 1 of Example is effective in suppressing surface oxidation of the barrier layer 17.

### [Evaluation of gm Characteristic]

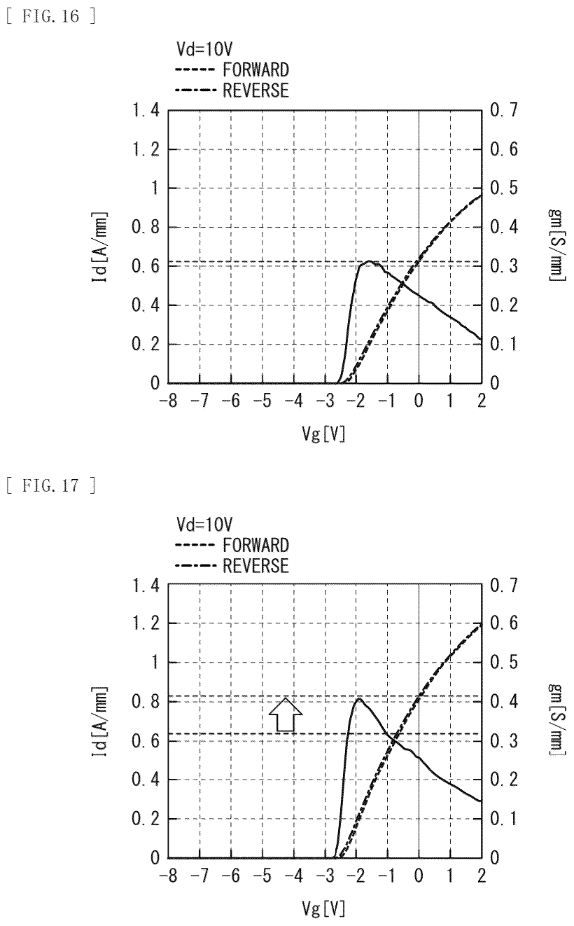

The current-voltage characteristics of Reference Example 2 and Example were measured, and the result is shown in FIG. 16 (Reference Example 2) and FIG. 17 (Example). In the sample of Example, a gm about 1.3 times higher than that of the sample of Reference Example 2 was obtained, and a derivative of a steeper I-V curve was also obtained. This is considered to be due to the improved crystallinity of the barrier layer 17 in the semiconductor device 1 of Example as compared with the semiconductor device 100B of Reference Example 2.

### 4. APPLICATION EXAMPLE

### 4-1. Semiconductor Module

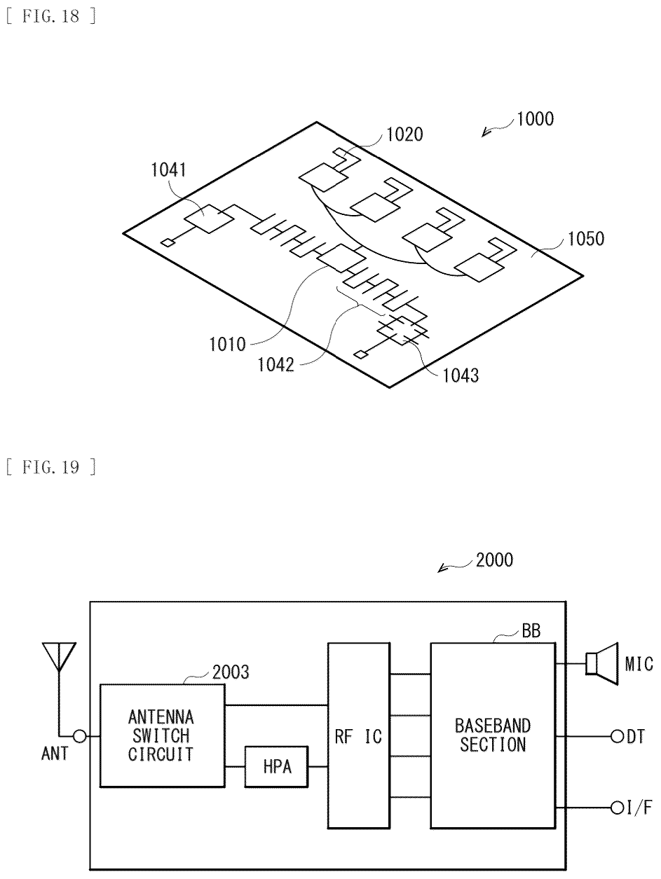

Subsequently, a semiconductor module as a first application example of the technique according to the present disclosure is described with reference to FIG. 18. FIG. 18 is a schematic perspective view illustrating a configuration of a semiconductor module 1000.

As illustrated in FIG. 18, the semiconductor module 1000 is an antenna-integrated module in which, for example, an edge antenna 1020 and a plurality of front-end components are mounted as a module on one chip 1050. For example, the edge antenna 1020 is formed in a plurality of arrays on the chip 1050. The front-end components are, for example, a switch 1010, a low noise amplifier 1041, a bandpass filter 1042, and a power amplifier 1043 or the like. For example, it is possible to use the semiconductor module 1000 as a transceiver for wireless communication.

The semiconductor module 1000 includes, for example, a semiconductor device (for example, the semiconductor device 1) of the above embodiment, etc., as a transistor included in the switch 1010, the low noise amplifier 1041, the power amplifier 1043 or the like. For example, in fifth generation mobile communication (5G), which uses a radio wave in a higher frequency band, there is a larger propagation loss of the radio wave. Therefore, it is desired that the semiconductor module 1000 compatible with 5G transmit a radio wave with higher power. Because the semiconductor module 1000 including the semiconductor device 1 enables an improvement of a device characteristic, it is possible to perform wireless communication with high power, low power consumption, and high reliability. In other words, it is possible to use the semiconductor module 1000 more appropriately for fifth generation mobile communication (5G).

### 4-2. Wireless Communication Apparatus

Next, a wireless communication apparatus as a second application example of a technique according to the present disclosure is described with reference to FIG. 19. FIG. 19 is a block diagram illustrating a configuration of a wireless communication apparatus 2000.

As illustrated in FIG. 19, the wireless communication apparatus 2000 includes an antenna ANT, an antenna switch circuit 2003, a high power amplifier HPA, a radio frequency integrated circuit RFIC (Radio Frequency Integrated Circuit), a baseband section BB, a voice output section MIC, a data output section DT, and an interface section I/F (for example, a wireless LAN (Wireless Local Area Network: W-LAN) or Bluetooth (registered trademark) or the like). For example, the wireless communication apparatus 2000 is a cellular phone system having multiple functions such as voice communication, data communication, or LAN connection, etc.

In the wireless communication apparatus 2000, at a time of transmission, a transmission signal is outputted from the baseband section BB to the antenna ANT via the radio frequency integrated circuit RFIC, the high power amplifier HPA, and the antenna switch circuit 203. In addition, in the wireless communication apparatus 2000, at a time of reception, a reception signal is inputted from the antenna ANT to the baseband section BB via the antenna switch circuit 2003 and the radio frequency integrated circuit RFIC. The reception signal processed in the baseband section BB is outputted to an outside of the wireless communication apparatus 2000 from, for example, the voice output section MIC, the data output section DT, or the interface section I/F.

The wireless communication apparatus 2000 includes a semiconductor device (for example, the semiconductor device 1) of the above embodiment or the like as a transistor included in the antenna switch circuit 2003, the high power amplifier HPA, the radio frequency integrated circuit RFIC, or the baseband section BB or the like. This makes it possible to further improve device characteristic, thus enabling the wireless communication apparatus 2000 to perform high output, low power consumption, and highly reliable wireless communication.

A technique according to the present disclosure has been described above with reference to some embodiments. Modification Examples 1 to 5, examples, and application examples. However, the technique according to the present disclosure is not limited to the above-described embodiments and the like, and various modifications are possible.

Furthermore, not all of the configurations and operations described in the embodiments are indispensable as the configurations and the operations of the present disclosure. For example, among the components of each embodiment, any component that is not recited in an independent claim which represents the most generic concept of the present disclosure is to be understood as an optional component.

Terms used throughout this specification and the appended claims should be construed as “non-limiting” terms. For example, the term “including” or “included” should be construed as “not limited to what is described as being included”. The term “having” should be construed as “not limited to what is described as being had”.

The terms used herein include terms that are used merely for convenience of description and not for the purpose of limiting the configuration and the operation. For example, terms such as “right,” “left,” “up,” and “down” merely indicate directions in the drawings being referred to. In addition, the terms “inside” and “outside” merely indicate a direction toward the center of a component of interest and a direction away from the center of a component of interest, respectively. The same applies to terms similar to these and to terms of similar intent.

It should be noted that the effects described herein are mere examples and are not limited, and there may be other effects.

It should be noted that the present technology may have the following configurations. According to the present technology in the following configuration, an intermediate layer including a second nitride semiconductor that includes Alₓ₂In_{y2}Ga_{(1-x2-y2)}N (0≤x2<1, 0≤y2<1) and satisfies (1−x1−y1)<(1−x2−y2) is provided within a barrier layer including a second nitride semiconductor including Alₓ₁In_{y1}Ga_{(1-x1-y1)}N (0<x1<1, 0<y1<1) and having a second baudgap larger than a first bandgap of a first nitride semiconductor included in the channel layer, thus improving the crystallinity of the barrier layer. This makes it possible to improve the heat resistance.

(1)

A semiconductor device, including:
a substrate;
a channel layer provided on one side of a surface of the substrate, the channel layer including a first nitride semiconductor having a first bandgap;
a barrier layer provided on an opposite side of the channel layer from the substrate and including a second nitride semiconductor, the second nitride semiconductor including Alₓ₁In_{y1}Ga_{(1-x1-y1)}N (0<x1<1, 0<y1<1) and having a second bandgap larger than the first bandgap of the first nitride semiconductor; and
an intermediate layer provided within the barrier layer and including a third nitride semiconductor, the third nitride semiconductor including Alₓ₂In_{y2}Ga_{(1-x2-y2)}N (0≤x2<1, 0≤y2<1), in which
(1−x1−y1)<(1−x2−y2) is satisfied.
   (2)

The semiconductor device according to (1), in which x2<x1 is satisfied.

(3)

The semiconductor device according to (1) or (2), in which 1−x2−y2>0.01 is satisfied.

(4)

The semiconductor device according to any one of (1) to (3), in which the intermediate layer has a thickness of 0.26 nm or more and 2.0 nm or less.

(5)

The semiconductor device according to any one of (1) to (4), in which
the barrier layer includes a first barrier layer and a second barrier layer, the first barrier layer being provided on the channel layer side with the intermediate layer in between and the second barrier layer being provided on the opposite side of the channel layer, and
the first barrier layer and the second barrier layer have an Al composition different from each other.
   (6)

The semiconductor device according to any one of (1) to (5), in which the x1 is greater than 0.7 and the y1 is less than 0.3.

(7)

The semiconductor device according to any one of (1) to (6), in which the barrier layer has a thickness of 2.0 nm or more and 20 nm or less.

(8)

The semiconductor device according to any one of (1) to (7), further including a protective layer on an opposite side of the barrier layer from the channel layer, the protective layer including Alₓ₃In_{y3}Ga_{(1-x3-y3)}N (0≤x3<1, 0≤y3<1) and satisfying (1−x1−y1)<(1−x3−y3).

(9)

The semiconductor device according to any one of (1) to (8), further including a first spacer layer and a second spacer layer stacked in sequence between the channel layer and the barrier layer, the first spacer layer including Alₓ₂In_{y2}Ga_{(1-x2-y2)}N (0<x4≤1, 0≤y4<1, 0≤x4+y4≤) and the second spacer layer including Alₓ₅In_{y5}Ga_{(1-x5-y5)}N (0<x5<x4≤1, 0≤y5<1, 0<x5+y5<1).

(10)

The semiconductor device according to any one of (1) to (9), in which the channel layer includes at least one type of GaN (gallium nitride), InGaN (indium gallium nitride), InN (indium nitride), AlGaN (aluminum gallium nitride), or AlInGaN (aluminum indium gallium nitride).

(11)

The semiconductor device according to any one of (1) to (10), in which the substrate includes at least one type of Si (silicon), sapphire, SiC (silicon carbide), GaN (gallium nitride), or AlN (aluminum nitride).

(12)

The semiconductor device according to any one of (9) to (11), further including:
an insulating film;
a gate electrode;
a source electrode; and
a drain electrode,
the insulating film, the gate electrode, the source electrode, and the drain electrode being provided on an opposite side of the barrier layer from the second spacer layer.
   (13)

The semiconductor device according to any one of (8) to (12), further including:
an insulating film;
a gate electrode;
a source electrode; and
a drain electrode,
the insulating film, the gate electrode, the source electrode, and the drain electrode being provided on the protective layer.
   (14)

The semiconductor device according to (13), in which the semiconductor device has a Schottky-type gate configuration in which the protective layer and the gate electrode have a Schottky junction.

(15)

A semiconductor module including a semiconductor device, the semiconductor device including:
a substrate,
a channel layer provided on one side of a surface of the substrate, the channel layer including a first nitride semiconductor having a first bandgap,
a barrier layer provided on an opposite side of the channel layer from the substrate and including a second nitride semiconductor, the second nitride semiconductor including Alₓ₁In_{y1}Ga_{(1-x1-y1)}N (0<x1<1, 0<y1<1) and having a second bandgap larger than the first bandgap of the first nitride semiconductor, and
an intermediate layer provided within the barrier layer and including a third nitride semiconductor, the third nitride semiconductor including Alₓ₂In_{y2}Ga_{(1-x2-y2)}N (0≤x2<1, 0≤y2<1), in which
the semiconductor device satisfies (1−x1−y1)<(1−x2−y2).
   (16)

A wireless communication apparatus including a semiconductor device, the semiconductor device including:
a substrate,
a channel layer provided on one side of a surface of the substrate, the channel layer including a first nitride semiconductor having a first bandgap,
a barrier layer provided on an opposite side of the channel layer from the substrate and including a second nitride semiconductor, the second nitride semiconductor including Alₓ₁In_{y1}Ga_{(1-x1-y1)}N (0<x1<1, 0<y1<1) and having a second bandgap larger than the first bandgap of the first nitride semiconductor, and
an intermediate layer provided within the barrier layer and including a third nitride semiconductor, the third nitride semiconductor including Alₓ₂In_{y2}Ga_{(1-x2-y2)}N (0≤x2<1, 0≤y2<1), in which
the semiconductor device satisfies (1−x1−y1)<(1−x2−y2).

The present application claims the benefit of Japanese Priority Patent Application JP2022-139301 filed with the Japan Patent Office on Sep. 1, 2022, the entire contents of which are incorporated herein by reference.

It should be understood by those skilled in the art that various modifications, combinations, sub-combinations and alterations may occur depending on design requirements and other factors insofar as they are within the scope of the appended claims or the equivalents thereof.

1. A semiconductor device comprising:
a substrate;
a channel layer provided on one side of a surface of the substrate, the channel layer including a first nitride semiconductor having a first bandgap;
a barrier layer provided on an opposite side of the channel layer from the substrate and including a second nitride semiconductor, the second nitride semiconductor including Alₓ₁In_{y1}Ga_{(1-x1-y1)}N (0<x1<1, 0<y1<1) and having a second bandgap larger than the first bandgap of the first nitride semiconductor; and
an intermediate layer provided within the barrier layer and including a third nitride semiconductor, the third nitride semiconductor including Alₓ₂In_{y2}Ga_{(1-x2-y2)}N (0≤x2<1, 0≤y2<1), wherein
(1−x1−y1)<(1−x2−y2) is satisfied.

2. The semiconductor device according to claim 1, wherein x2<x1 is satisfied.

3. The semiconductor device according to claim 1, wherein 1−x2−y2>0.01 is satisfied.

4. The semiconductor device according to claim 1, wherein the intermediate layer has a thickness of 0.26 nm or more and 2.0 nm or less.

5. The semiconductor device according to claim 1, wherein
the barrier layer includes a first barrier layer and a second barrier layer, the first barrier layer being provided on the channel layer side with the intermediate layer in between and the second barrier layer being provided on the opposite side of the channel layer, and
the first barrier layer and the second barrier layer have an Al composition different from each other.

6. A semiconductor device according to claim 1, wherein the x1 is greater than 0.7 and the y1 is less than 0.3.

7. The semiconductor device according to claim 1, wherein the barrier layer has a thickness of 2.0 nm or more and 20 nm or less.

8. The semiconductor device according to claim 1, further comprising a protective layer on an opposite side of the barrier layer from the channel layer, the protective layer including Alₓ₃In_{y3}Ga_{(1-x3-y3)}N (0≤x3<1, 0≤y3<1) and satisfying (1−x1−y1)<(1−x3−y3).

9. The semiconductor device according to claim 1, further comprising a first spacer layer and a second spacer layer stacked in sequence between the channel layer and the barrier layer, the first spacer layer including Alₓ₄In_{y4}Ga_{(1-x4-y4)}N (0<x4≤1, 0≤y4<1, 0≤x4+y4≤1) and the second spacer layer including Alₓ₅In_{y5}Ga_{(1-x5-y5)}N (0<x5<x4≤1, 0≤y5<1, 0<x5+y5<1).

10. The semiconductor device according to claim 1, wherein the channel layer includes at least one type of GaN (gallium nitride), InGaN (indium gallium nitride), InN (indium nitride), AlGaN (aluminum gallium nitride), or AlInGaN (aluminum indium gallium nitride).

11. The semiconductor device according to claim 1, wherein the substrate includes at least one type of Si (silicon), sapphire, SiC (silicon carbide), GaN (gallium nitride), or AlN (aluminum nitride).

12. The semiconductor device according to claim 9, further comprising:
an insulating film;
a gate electrode;
a source electrode; and
a drain electrode,
the insulating film, the gate electrode, the source electrode, and the drain electrode being provided on an opposite side of the barrier layer from the second spacer layer.

13. The semiconductor device according to claim 8, further comprising:
an insulating film;
a gate electrode;
a source electrode; and
a drain electrode,
the insulating film, the gate electrode, the source electrode, and the drain electrode being provided on the protective layer.

14. The semiconductor device according to claim 13, wherein the semiconductor device has a Schottky-type gate configuration in which the protective layer and the gate electrode have a Schottky junction.

15. A semiconductor module comprising a semiconductor device, the semiconductor device including:
a substrate,
a channel layer provided on one side of a surface of the substrate, the channel layer including a first nitride semiconductor having a first bandgap,
a barrier layer provided on an opposite side of the channel layer from the substrate and including a second nitride semiconductor, the second nitride semiconductor including Alₓ₁In_{y1}Ga_{(1-x1-y1)}N (0<x1<1, 0<y1<1) and having a second bandgap larger than the first baudgap of the first nitride semiconductor, and
an intermediate layer provided within the barrier layer and including a third nitride semiconductor, the third nitride semiconductor including Alₓ₂In_{y2}Ga_{(1-x2-y2)}N (0≤x2<1, 0≤y2<1), wherein
the semiconductor device satisfies (1−x1−y1)<(1−x2−y2).

16. A wireless communication apparatus comprising a semiconductor device, the semiconductor device including:
a substrate,
a channel layer provided on one side of a surface of the substrate, the channel layer including a first nitride semiconductor having a first bandgap,
a barrier layer provided on an opposite side of the channel layer from the substrate and including a second nitride semiconductor, the second nitride semiconductor including Alₓ₁In_{y1}Ga_{(1-x1-y1)}N (0<x1<1, 0<y1<1) and having a second bandgap larger than the first bandgap of the first nitride semiconductor, and
an intermediate layer provided within the barrier layer and including a third nitride semiconductor, the third nitride semiconductor including Alₓ₂In_{y2}Ga_{(1-x2-y2)}N (0≤x2<1, 0≤y2<1), wherein
the semiconductor device satisfies (0−x1−y1)<(1−x2−y2).
